(19) United States
(12) Patent Application Publication
(10) Pub. No.: US 2004/0238026 A1
(43) Pub. Date: Dec. 2, 2004

(54) Dye sensitizing solar battery unit, and substrate assembly and sealing structure for dye sensitizing solar battery unit

(76) Inventor: Kozo Miyoshi, Kitamoto-shi (JP)

Correspondence Address: BACHMAN & LAPOINTE, P.C., 900 CHAPEL STREET, SUITE 1201, NEW HAVEN, CT, 06510, US

(21) Appl. No.: 10/858,679

(22) Filed: Jun. 1, 2004

(30) Foreign Application Priority Data
Jun. 2, 2003 (JP) 2003-156368

(51) Int. Cl. H01L 31/00

(52) U.S. Cl. 136/263; 136/244

(57) ABSTRACT

There is provided a dye sensitizing solar battery unit having a high durability in its bonding portion. A fitting protruding wall portion 11C is formed so as to extend along the peripheral portion of a photoelectrode substrate 11 of a resin, and afitted protruding wall portion 12A is formed so as to extend along the periphery of a counter electrode substrate 12 of a resin. By fitting the fitting protruding wall portion 11C into a space defined by the fitted protruding wall portion 12A, the fitting protruding wall portion 11C is caused to tightly contact the fitted protruding wall portion 12A to enhance the bonding strength therebetween. In addition, a plurality of spacer portions 11B are integrally formed on the photoelectrode substrate 11 at regular intervals for holding a predetermined distance between the photoelectrode substrate 11 and the counter electrode substrate 12. Thus, the plurality of spacer portions 11B are uniformly arranged to enhance the durability of the dye sensitizing solar battery unit.

### BACKGROUND OF THE INVENTION

1. Field of the Invention

The present invention relates to a dye sensitizing solar battery unit, a substrate assembly for a dye sensitizing solar battery unit, and a sealing structure for a dye sensitizing solar battery unit.

2. Description of the Prior Art

In recent years, from the point of view of environmental issues, solar batteries for converting light energy to electric energy have been widely noticed. In particular, dye sensitizing solar batteries have been widely noticed since the costs for producing them can be low. Originally, dye sensitizing solar batteries are not intended for practical use since they have a low photoelectric transfer efficiency. Recently, there has been developed a technique for increasing the surface area of a semiconductor electrode to cause the electrode to absorb a large amount of dye to conspicuously enhance the photoelectric transfer efficiency of a dye sensitizing solar battery (see, e.g., Japanese Patent Unexamined Publication No. 5-504023 (National Publication of Translated Version of PCT/EP91/00734)).

As an example of such a conventional technique, there is known a dye sensitizing solar battery unit 100 shown in FIG. 20. The dye sensitizing solar battery unit 100 comprises a transparent substrate 101, and a conductive substrate 103 having a recessed portion 103A in which an electrolytic solution 102 is filled, the flat face of the transparent substrate 101 being bonded to the flat face of the conductive substrate 103 in a bonding region 104 with an adhesion or the like (see, e.g., Japanese Patent Laid-Open Nos. 11-307141 and 2000-30767).

As another example, there is also known a dye sensitizing solar battery unit 200 shown in FIG. 21. As shown in FIG. 21, the dye sensitizing solar battery unit 200 comprises a photoelectrode substrate 201, a counter electrode substrate 202, and a sealing material 203 of an epoxy resin or the like for bonding the photoelectrode substrate 201 to the counter electrode substrate 202. On a surface of the photoelectrode substrate 201 facing the counter electrode substrate 202, a transparent electrode film 204 and a porous semiconductor film 205 of titanium oxide or the like are sequentially stacked. On the porous semiconductor film 205, a dye has been absorbed.

On other hand, on a surface of the counter electrode substrate 202 facing the photoelectrode substrate 201, a counter electrode 206 is formed. Between the porous semiconductor film 205 of the photoelectrode substrate 201 and the counter electrode 206 of the counter electrode substrate 202, spherical spacers 207 of a resin material or silicon dioxide are arranged, and an electrolytic solution (redox electrolytic solution) 208 is filled in a space defined therebetween.

However, in the above described dye sensitizing solar battery unit 100 shown in FIG. 20, there is a problem in that the adhesive or the like arranged between the substrates 101 and 103 in the bonding region 104 contacts and deteriorate with the electrolytic solution 102, since electrolytic solutions for use in dye sensitizing solar batteries are very corrosive. Thus, in the dye sensitizing solar battery unit 100 with the above described construction, there is a problem to be solved with respect to bonding strength.

In the dye sensitizing solar battery unit 101, there is also a problem in that it is difficult to align the transparent substrate 101 with the conductive substrate 103 since the bonding faces of both of the substrates 101 and 103 are flat.

Moreover, there is a problem in that the dye sensitizing solar battery unit 200 shown in FIG. 21 is easily damaged so as to have a low reliability, since the electrolytic solution 208 is easy to corrode the sealing material 203. In addition, since the spacers 207 for defining a gap between the photoelectrode substrate 201 and the counter electrode substrate 202 are spread to be arranged, there are some cases where the spacers 207 may aggregate, so that it is difficult to uniformly arrange the spacers 207.

### SUMMARY OF THE INVENTION

It is therefore an object of the present invention to eliminate the aforementioned problems and to provide a dye sensitizing solar battery unit having a high durability in its bonding portion, and a sealing structure for sealing the dye sensitizing solar battery unit.

It is another object of the present invention to provide a dye sensitizing solar battery unit which has a uniform gap between substrates and which has a high power generation efficiency, the substrates being capable of being easily aligned with each other, a substrate assembly for such a dye sensitizing solar battery unit, and a sealing structure for sealing the dye sensitizing solar battery unit.

In order to accomplish the aforementioned and other objects, according to one aspect of the present invention, a dye sensitizing solar battery unit comprises: a photoelectrode substrate on which a semiconductor electrode is formed; a counter electrode substrate on which a counter electrode is formed; and an electrolyte filled in a space defined by the photoelectrode substrate and the counter electrode substrate, the counter electrode facing the semiconductor electrode via the electrolyte so that a potential difference is produced between the counter electrode and the semiconductor electrode by photoelectric transfer, wherein one of the photoelectrode substrate and the counter electrode substrate has a fitting portion which is formed so as to surround a region in which the semiconductor electrode faces the counter electrode, and the other of the photoelectrode substrate and the counter electrode substrate has a fitted portion which is formed so as to surround the region, the fitting portion being fitted into a space defined by the fitted portion.

In this dye sensitizing solar battery unit, the fitted portion may be a protruding wall which protrudes from the other of the photoelectrode substrate and the counter electrode substrate toward the one of the photoelectrode substrate and the counter electrode substrate. The photoelectrode substrate and the counter electrode substrate may be formed of a resin. In this case, the fitting portion may be bonded or welded to the fitted portion in a bonding surface which is apart from the electrolyte. The dye sensitizing solar battery unit may have a spacer portion formed so as to be integrated with one of the photoelectrode substrate and the counter electrode substrate for holding a predetermined distance between the photoelectrode substrate and the counter electrode substrate. One of the photoelectrode substrate and the counter electrode substrate may be light-transmittable, and may have a condensing portion for changing a traveling direction of incident light toward the semiconductor electrode.

According to another aspect of the present invention, a substrate assembly for a dye sensitizing solar battery unit, comprises: a photoelectrode substrate on which a semiconductor electrode is formed; and a counter electrode substrate on which a counter electrode is formed, the counter electrode facing the semiconductor electrode, wherein one of the photoelectrode substrate and the counter electrode substrate has a fitting portion which is formed so as to surround a region in which the semiconductor electrode faces the counter electrode, and the other of the photoelectrode substrate and the counter electrode substrate has a fitted portion which is formed so as to surround the region, the fitting portion being fitted into a space defined by the fitted portion.

In this substrate assembly for a dye sensitizing solar battery unit, the photoelectrode substrate and the counter electrode substrate may be formed of a resin, and the photoelectrode substrate may be light-transmittable. The substrate assembly for a dye sensitizing solar battery unit may have a spacer portion formed so as to be integrated with one of the photoelectrode substrate and the counter electrode substrate for holding a predetermined distance between the photoelectrode substrate and the counter electrode substrate. One of the photoelectrode substrate and the counter electrode substrate may have a condensing portion for changing a traveling direction of incident light toward the semiconductor electrode.

According to a further aspect of the present invention, a sealing structure for sealing a dye sensitizing solar battery unit, comprises: a fitting portion formed on one of a photoelectrode substrate on which a semiconductor electrode is formed, and a counter electrode substrate on which a counter electrode is formed, the counter electrode facing the semiconductor electrode via an electrolyte, which is filled in a space defined by the photoelectrode substrate and the counter electrode substrate, so that a potential difference is produced between the counter electrode and the semiconductor electrode by photoelectric transfer, the fitting portion extending so as to surround a region in which the semiconductor electrode faces the counter electrode; and a fitted portion formed on the other of the photoelectrode substrate and the counter electrode substrate, the fitted portion extending so as to surround the region, the fitting portion being fitted into a space defined by the fitted portion.

In this sealing structure, the fitting portion may be bonded or welded to the fitted portion in a region which is apart from the electrolyte.

### BRIEF DESCRIPTION OF THE DRAWINGS

The present invention will be understood more fully from the detailed description given herebelow and from the accompanying drawings of the preferred embodiments of the invention. However, the drawings are not intended to imply limitation of the invention to a specific embodiment, but are for explanation and understanding only.

In the drawings:

FIG. 1 is an exploded perspective view of the first preferred embodiment of a dye sensitizing solar battery unit according to the present invention;

FIG. 2 is a perspective view of the first preferred embodiment of a dye sensitizing solar battery unit according to the present invention;

FIG. 3A is a sectional view taken along line IIIA-IIIA of FIG. 2, and FIG. 3B is a sectional view taken along line IIIB-IIIB of FIG. 2;

FIG. 4 is a sectional view of a principal part of the first preferred embodiment of a dye sensitizing solar battery unit according to the present invention;

FIG. 5 is a sectional view of a principal part of a sealing portion of the first preferred embodiment of a dye sensitizing solar battery unit according to the present invention;

FIG. 6 is a plan view showing an example of connection and arrangement of a plurality of dye sensitizing solar battery units in the first preferred embodiment according to the present invention;

FIG. 7 is a sectional view of a principal part of a first modified example of the first preferred embodiment of a dye sensitizing solar battery unit according to the present invention;

FIG. 8 is a sectional view of a principal part of a second modified example of the first preferred embodiment of a dye sensitizing solar battery unit according to the present invention;

FIG. 9 is a sectional view of a principal part of a third modified example of the first preferred embodiment of a dye sensitizing solar battery unit according to the present invention;

FIG. 10 is a sectional view of a principal part of a fourth modified example of the first preferred embodiment of a dye sensitizing solar battery unit according to the present invention;

FIG. 11 is a sectional view of a principal part of a fifth modified example of the first preferred embodiment of a dye sensitizing solar battery unit according to the present invention;

FIG. 12 is a sectional view of a principal part of a sixth modified example of the first preferred embodiment of a dye sensitizing solar battery unit according to the present invention;

FIG. 13 is a sectional view of a principal part of a seventh modified example of the first preferred embodiment of a dye sensitizing solar battery unit according to the present invention;

FIG. 14 is a sectional view of a principal part of the second preferred embodiment of a dye sensitizing solar battery unit according to the present invention;

FIG. 15 is a sectional view of the third preferred embodiment of a dye sensitizing solar battery unit according to the present invention;

FIG. 16 is a sectional view of a principal part of the third preferred embodiment of a dye sensitizing solar battery unit according to the present invention;

FIG. 17 is a sectional view of a principal part of a modified example of the third preferred embodiment of a dye sensitizing solar battery unit according to the present invention;

FIG. 18 is an exploded perspective view of the fourth preferred embodiment of a dye sensitizing solar battery unit according to the present invention;

FIG. 19 is a sectional view of the fourth preferred embodiment of a dye sensitizing solar battery unit according to the present invention;

FIG. 20 is a sectional view of a conventional dye sensitizing solar battery unit; and

FIG. 21 is a sectional view of another conventional dye sensitizing solar battery unit.

### DESCRIPTION OF THE PREFERRED EMBODIMENTS

Referring now to the accompanying drawings, the preferred embodiments of a dye sensitizing solar battery unit according to the present invention will be described below in detail.

[First Preferred Embodiment]

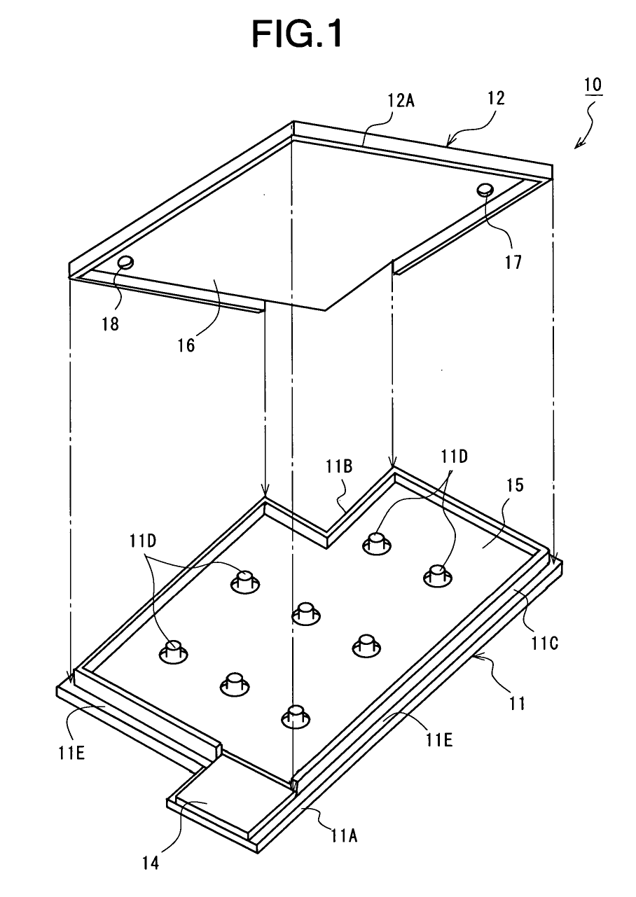

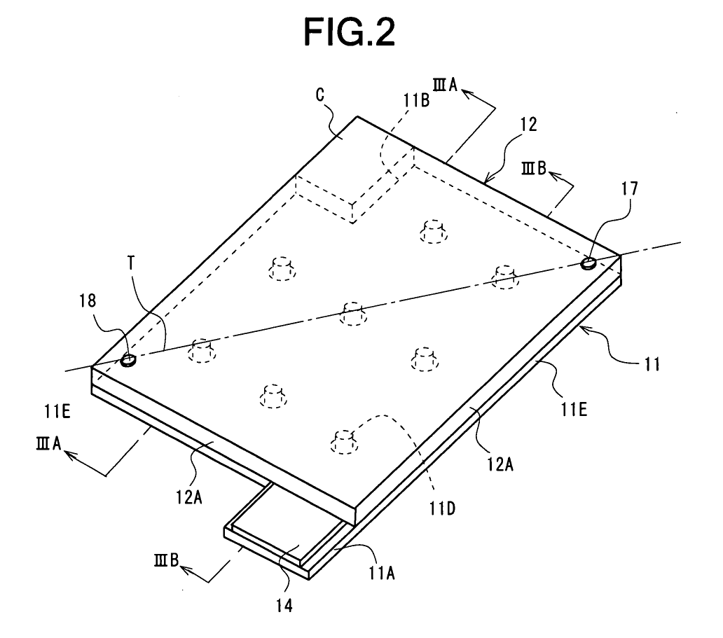

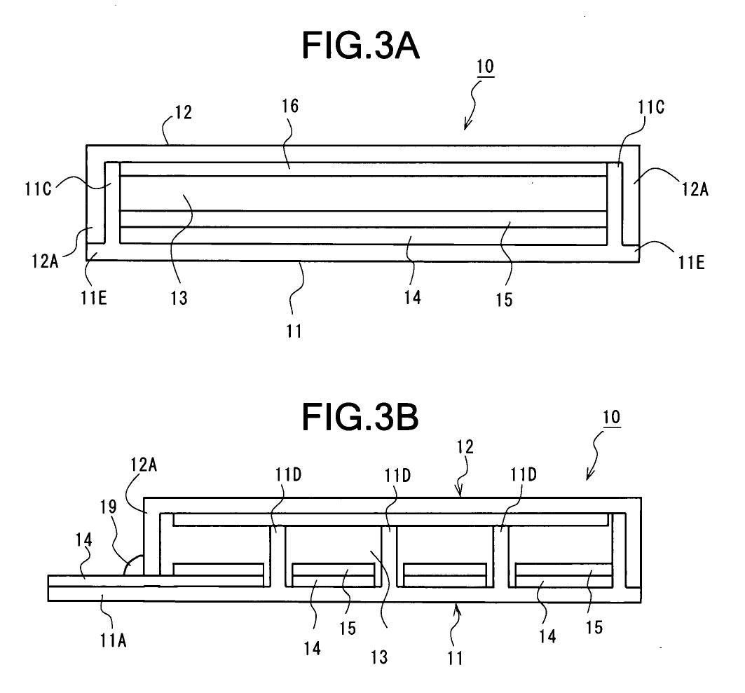

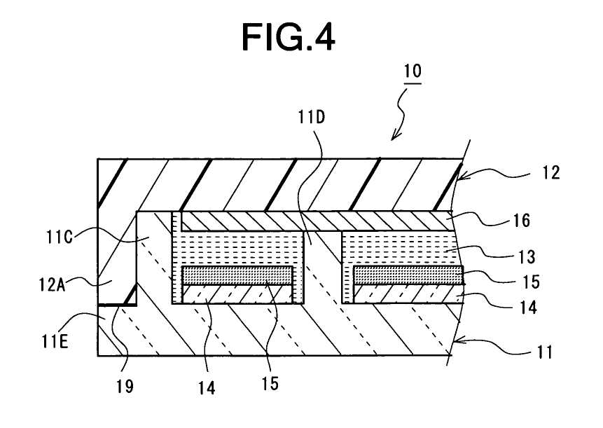

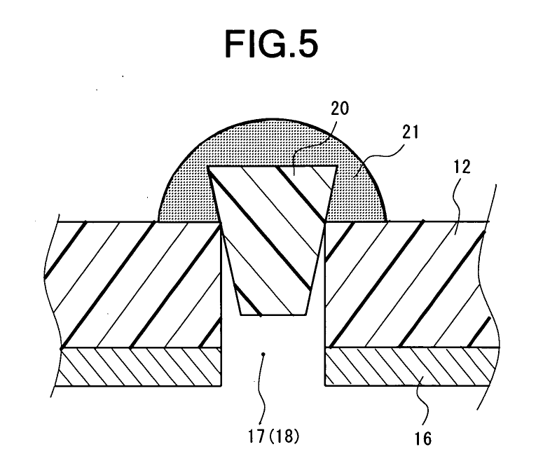

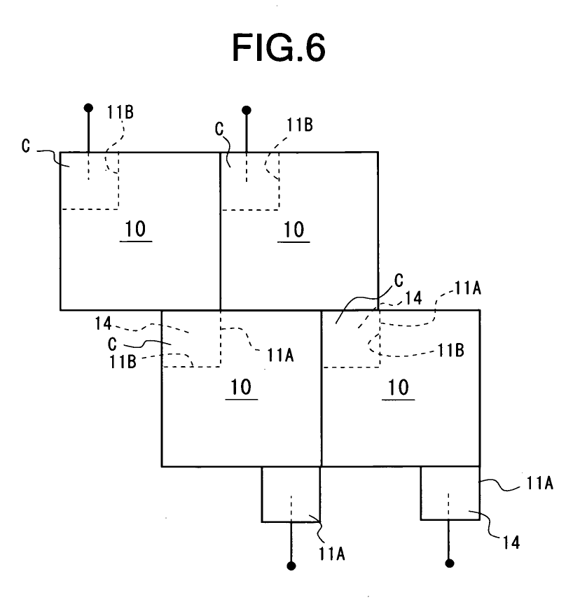

FIGS. 1 through 6 show the first preferred embodiment of a dye sensitizing solar battery unit according to the present invention. FIG. 1 is an exploded perspective view of the first preferred embodiment of a dye sensitizing solar battery unit 10 according to the present invention, and FIG. 2 is a perspective view of the dye sensitizing solar battery unit 10. FIG. 3A is a sectional view taken along line IIIA-IIIA of FIG. 2, and FIG. 3B is a sectional view taken along line IIIB-IIIB of FIG. 2. FIGS. 4 and 5 are sectional views of principal parts of the dye sensitizing solar battery unit 10, and FIG. 6 is a plan view showing an example of connection and arrangement of the dye sensitizing solar battery units 10.

The dye sensitizing solar battery unit 10 in this preferred embodiment generally comprises a photoelectrode substrate 11, a counter electrode substrate 12 facing the photoelectrode substrate 11, and an electrolytic solution 13 serving as an electrolyte (see FIG. 4) filled in a space between the substrates 11 and 12.

The photoelectrode substrate 11 is formed of a resin material capable of sufficiently transmitting light. The photoelectrode substrate 11 has a substantially rectangular planar shape, and has a rectangular transparent electrode ejecting portion 11A which extends from a corner of the photoelectrode substrate 11 in a lateral direction while protruding from one edge of the photoelectrode substrate 11 in a longitudinal direction. The photoelectrode substrate 11 has a rectangular cut-out portion 11B in the opposite corner portion to the transparent electrode ejecting portion 11A in diagonal directions.

The photoelectrode substrate 11 has a fitting protruding wall portion 11C which protrudes from a substrate surface thereof (a surface of the photoelectrode substrate 11 facing the counter electrode substrate 12) in a direction perpendicular to the substrate surface and which extends along the periphery thereof, except for a portion in which the transparent electrode ejecting portion 11A is formed. In a region surrounded by the fitting protruding wall portion 11C on the photoelectrode substrate 11, a plurality of spacer portions 11D having a predetermined height are arranged in regular intervals so as to protrude. Outside of the fitting protruding wall portion 11C, the photoelectrode substrate 11 has a flange portion 11E having a predetermined width. The photoelectrode substrate 11 with such a construction is formed of a resin to be precisely molded by a molding die.

On the substrate surface of the photoelectrode substrate 11 facing the counter electrode substrate 12, a transparent electrode film 14 is formed in the entire region, except for the peripheral portion and a region in which the spacer portions 11D are formed. The transparent electrode film 14 is formed of, e.g., indium tin oxide (ITO). On the transparent electrode film 14, a semiconductor film 15 is stacked in a region other than the transparent electrode ejecting portion 11A and spacer portions lD. The semiconductor film 15 is formed of, e.g., porous titanium dioxide (TiO₂), and absorbs a sensitizing dye thereon to carry the dye thereon.

The counter electrode substrate 12 is formed of a resin, which is substantially the same as the resin of the photoelectrode substrate 11, to be precisely molded by a molding die. It is not required for the counter electrode substrate 12 to have a high light transmittance. The resin material of the photoelectrode substrate 11 and counter electrode substrate 12 may be acrylic resin, polyethylene terephthalate (PET), polyolefin or polycarbonate (PC).

As shown in FIGS. 1 and 2, the counter electrode substrate 12 substantially has the same rectangular planar shape as that of the photoelectrode substrate 11, except for the transparent electrode ejecting portion 11A and the cut-out portion 11B. That is, the counter electrode substrate 12 has a rectangular corner portion C without cutting a portion corresponding to the cut-out portion 11B of the photoelectrode substrate 11 out thereof. On the inside surface of the corner portion C (on a surface of the corner portion C facing the photoelectrode substrate 11) , a counter electrode 16, which wi11 be described later, is exposed to function as an electrode ejecting portion.

The counter electrode substrate 12 has a fitted protruding wall portion 12A which protrudes toward the photoelectrode substrate 11 and which extends along the periphery of the counter electrode substrate 12, except for the portion (corner portion C) facing the cut-out portion 11B of the photoelectrode substrate 11. As shown in FIG. 4, the fitted protruding wall portion 12A is designed so that the fitting protruding wall portion 11C of the photoelectrode substrate 11 is tightly fitted into a space defined by the fitted protruding wall portion 12A when the counter electrode substrate 12 is mounted on the photoelectrode substrate 11. The height of the fitted protruding wall portion 12A is substantially equal to the height of the fitting protruding wall portion 11C of the photoelectrode substrate 11.

In the substantially entire region of the substrate surface of the counter electrode substrate 12, slightly inside of the fitted protruding wall portion 12A, the counter electrode 16 coated with a catalyst of, e.g., platinum, is formed.

In this preferred embodiment, as shown in FIG. 2, the counter electrode substrate 12 and the counter electrode film 16 have an electrolytic solution injecting hole 17 in the vicinity of one end of one diagonal line T of two diagonal lines of the rectangular counter electrode substrate 12, which does not pass through the corner portion C, and an exhaust hole 18 in the vicinity of the other end of the diagonal line T.

When the photoelectrode substrate 11 and the counter electrode substrate 12 are bonded to each other, the structure shown in FIGS. 3A, 3B and 4 is obtained. That is, as shown in FIGS. 3A and 4, the fitting protruding wall portion 11C of the photoelectrode substrate 11 is tightly fitted into a space surrounded by the fitted protruding wall portion 12A of the counter electrode substrate 12. In this preferred embodiment, as shown in FIG. 4, since the height of the fitting protruding wall portion 11C is designed to be equal to the height of the fitted protruding wall portion 12A, the end face of the fitting protruding wall portion 11C of the photoelectrode substrate 11 tightly contacts the inside surface of the counter electrode substrate 12, and the end face of the fitted protruding wall portion 12A of the counter electrode substrate 12 tightly contacts the facing surface of the flange portion 11E of the photoelectrode substrate 11. Since the fitting protruding wall portion 11C is thus tightly fitted into the space surrounded by the fitted protruding wall portion 12A, it is possible to physically hold the fluid-tightness of bonding.

In this preferred embodiment, as shown in FIG. 4, the end face of the fitted protruding wall portion 12A of the counter electrode substrate 12 is bonded to the facing surface of the flange portion 11E of the photoelectrode substrate 11 with an adhesive 19. Thus, the adhesive 19 does not directly contact the electrolytic solution 13 filled in the dye sensitizing solar battery unit 10, so that the deterioration of the adhesive 19 is inhibited. Therefore, in the dye sensitizing solar battery unit 10 in this preferred embodiment, the bonding strength of the photoelectrode substrate 11 to the counter electrode substrate 12 can be high, so that it is possible to realize a high durability. Furthermore, the adhesive 19 may be an epoxy resin, phenol resin, silicon resin or acrylic resin, and may be applied by means of, e.g., a dispenser.

As shown in FIG. 3B, in the transparent electrode ejecting portion 11A of the photoelectrode substrate 11, the end face of the fitted protruding wall portion 12A of the counter electrode substrate 12 tightly contacts the transparent electrode 14. In this preferred embodiment, the outside face of the end portion of the fitted protruding wall portion 12A is bonded to the transparent electrode 14 with the adhesive 19. Thus, also in a region in which the end face of the fitted protruding wall portion 12A of the counter electrode substrate 12 tightly contacts the transparent electrode 14, it is possible to prevent the adhesive 19 from directly contacting the electrolytic solution 13, so that it is possible to improve the durability of bonding.

With respect to the bonding of the corner portion C, in which the fitted protruding wall portion 12A of the counter electrode substrate 12 is not formed, to the fitting protruding wall portion 11C formed along the edge of a portion in which the cut-out portion 11B of the photoelectrode substrate 11 is formed, the end face of the fitting protruding wall portion 11C tightly contacts the counter electrode film 16, and the outside portion of the end face of the fitting protruding wall portion 11C is bonded to the counter electrode 16 with an adhesive (not shown).

As shown in FIGS. 3B and 4, the spacer portions 11D protruding from the photoelectrode substrate 11 contact the counter electrode film 16 on the counter electrode substrate 12 to hold a predetermine distance between the photoelectrode substrate 11 and the counter electrode substrate 12.

In order to fill the electrolytic solution 13 in the structure wherein the photoelectrode substrate 11 and the counter electrode substrate 12 are bonded to each other, the electrolytic solution 13 may be injected from the electrolytic solution injecting hole 17, which is formed in the counter electrode substrate 12, while exhausting gas from the exhaust hole 18. As shown in FIG. 5, after the filling of the electrolytic solution 13 is completed, the electrolytic solution injecting hole 17 and the exhaust hole 18 are closed by a closing member 20, and the top end portion of the closing member 20 is sealed with an adhesive 21.

While the adhesive 19 has been used as a fixing means on the fitting portion of the photoelectrode substrate 11 to the counter electrode substrate 12 in the above described preferred embodiment, a fixing technique or material, such as ultrasonic welding or an ultraviolet curable resin, may be used. When an ultraviolet curable resin is used, a masking is preferably applied so as to irradiate only the ultraviolet curable resin with light in order to prevent the dye, which is absorbed on the semiconductor film 15, from being damaged.

The operation and advantageous effects of the dye sensitizing solar battery unit 10 in the above described first preferred embodiment will be described below.

In this preferred embodiment, the photoelectrode substrate 11 and the counter electrode substrate 12 are tightly bonded to each other by fitting the fitting protruding wall portion 11C into the space surrounded by the fitted protruding wall portion 12A. Since the photoelectrode substrate 11 and the counter electrode substrate 12 are formed of a resin to be precisely molded by a molding die, the fitting protruding wall portion 11C and the fitted protruding wall portion 12A tightly contact each other on the bonding interface therebetween. By bonding a part of the bonding interface, which is difficult to directly contact the electrolytic solution 13, i.e., which is apart from the electrolytic solution 13, with the adhesive 19, it is difficult for the adhesion 19 to deteriorate with the electrolytic solution 13. Therefore, the bonding strength of the photoelectrode substrate 11 to the counter electrode substrate 12 can be enhanced to inhibit the adhesive 19 from deteriorating with the electrolytic solution 13, so that the durability of the dye sensitizing solar battery unit 10 can be improved.

In this preferred embodiment, since the photoelectrode substrate 11 is bonded to the counter electrode substrate 12 by fitting the fitting protruding wall portion 11C into the space surrounded by the fitted protruding wall portion 12A, the substrates 11 and 12 can be aligned with each other by the fitting, so that it is possible to improve assembling efficiency.

In this preferred embodiment, since the photoelectrode substrate 11 is integrally formed with the spacer portions 11D, it is not required to spread spherical spacers unlike conventional units. Since the spacer portions 11D are formed by a molding die so that the position and dimension thereof are precise to hold a predetermined distance between the photoelectrode substrate 11 and the counter electrode substrate 12. Therefore, the battery structure comprising the semiconductor film 15, the counter electrode 16 and the electrolytic solution 13 provided therebetween can be maintained in the optimum state.

In the dye sensitizing solar battery unit 10 with such a construction, if sunlight is incident on the photoelectrode substrate 11 from the outside, the sensitizing dye absorbed and carried on the semiconductor film 15 is excited so that its electronic state changes from a ground state to an excited state. The excited electrons of the sensitizing dye are injected into the conduction band of TiO₂ of the semiconductor film 15 to pass through an external circuit to move to the counter electrode film 16. The electrons moving to the counter electrode film 16 are carried on ions in the electrolytic solution 13 to return to the sensitizing dye. Such operations are repeated to take electric energy out. Furthermore, in this preferred embodiment, the explanation of the external circuit is omitted.

The above described dye sensitizing solar battery unit 10 can be used for carrying out power generation with sunlight energy in a light irradiating place. Specifically, as shown in FIG. 6, if the transparent electrode ejecting portion 11A of the photoelectrode substrate 11 of one of adjacent two of a plurality of dye sensitizing solar battery units 10 is arranged in the cut-out portion 11B of the photoelectrode substrate 11 of the other of the adjacent two of the dye sensitizing solar battery units 10 to arrange each of the transparent electrodes 14, each of which is exposed in a corresponding one of the transparent electrode ejecting portions 11A, on a portion of a corresponding one of the counter electrodes 16, each of which is exposed in the corner portion C of a corresponding one of the counter electrode substrates 12, to electrically connect the plurality of dye sensitizing solar battery units 10 in series or to electrically connect the series of dye sensitizing solar battery units 10 in parallel, it is possible to obtain electric energy having a desired voltage. Such electric energy can be stored in a storage battery.

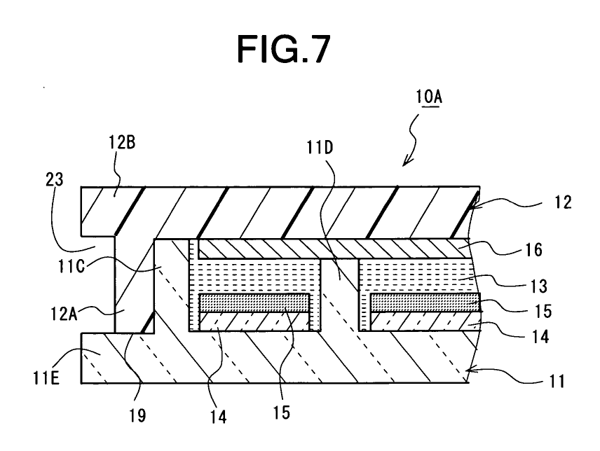

FIG. 7 shows a dye sensitizing solar battery unit 10A as a first modified example of the first preferred embodiment according to the present invention. In the first modified example, the same reference numbers as those in the first preferred embodiment are given to the same portions as those in the first preferred embodiment to omit the detailed explanation thereof.

The dye sensitizing solar battery unit 10A substantially had the same construction as that of the dye sensitizing solar battery unit 10 in the first preferred embodiment, except that the peripheral portions of the photoelectrode substrate 11 and counter electrode substrate 12 have slightly different constructions from those in the first preferred embodiment.

In the dye sensitizing solar battery unit 10A in the first modified example, the flange portion 11E of the photoelectrode substrate 11 extends to the outside so as to be slightly longer than that in the first preferred embodiment. The peripheral portion 12B of the counter electrode substrate 12 in the first example also extends to the outside so as to be slightly longer than that in the first preferred embodiment, so that the counter electrode substrate 12 substantially has the same size as that of the photoelectrode substrate 11. Thus, as shown in FIG. 7, when the photoelectrode substrate 11 and the counter electrode substrate 12 are bonded to each other, a recessed portion 23 defined by the flange portion 11E, fitted protruding wall portion 12A and peripheral portion 12B is formed in the peripheral portion of the dye sensitizing solar battery unit 10A. In the first example, if the recessed portion 23 is filled with, e.g., an adhesive or sealing material, it is possible to further improve the bonding strength. Therefore, the durability of the dye sensitizing solar battery unit 10A can be improved.

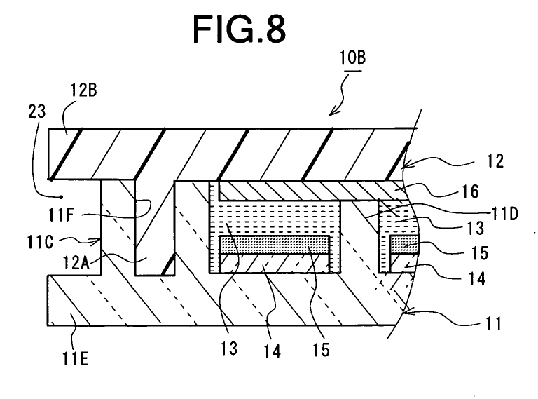

FIG. 8 is a sectional view of a principal part of a dye sensitizing solar battery unit 10B as a second modified example of the first preferred embodiment according to the present invention. The dye sensitizing solar battery unit 10B in the second modified example substantially has the same construction as that on the dye sensitizing solar battery unit 10 in the above described first preferred embodiment, except that the fitting protruding wall portion 11C and fitted protruding wall portion 12A have different constructions from those in the above described first preferred embodiment and that the peripheral portion 12B of the counter electrode substrate 12 extends to the outside to such an extent that the flange portion 11E extends similar to the above described first modified example.

Specifically, as shown in FIG. 8, in the dye sensitizing solar battery unit 10B, a groove 11F substantially having the same depth as the height of the fitting protruding wall portion 11C is formed in the end face of the fitting protruding wall portion 11C of the photoelectrode substrate 11 so as to extend in a direction in which the fitting protruding wall portion 11C extends (in a direction in which the periphery of the photoelectrode substrate 11 extends).

The fitted protruding wall portion 12A is tightly fitted into the groove 11F. With such a construction, the area of the bonding interface between the fitting protruding wall portion 11C and the fitted protruding wall portion 12A increases to more effectively prevent the electrolytic solution 13 from leaking out of the bonding interface.

In the second modified example, in the peripheral side of the dye sensitizing solar battery unit 10B, the recessed portion 23is formed by the flange portion 11E of the photoelectrode substrate 11, the peripheral portion 12B of the counter electrode substrate 12 and the fitting protruding wall portion 11C. Also in the second modified example, if the recessed portion 23 is filled with, e.g., an adhesive or sealing material, the bonding strength can be further improved, so that the durability of the dye sensitizing solar battery unit 10B can be improved.

Furthermore, in the second modified example, the end face of the fitted protruding wall portion 12A may be bonded to the photoelectrode substrate 11 by, e.g., ultrasonic welding, without the need of any adhesives.

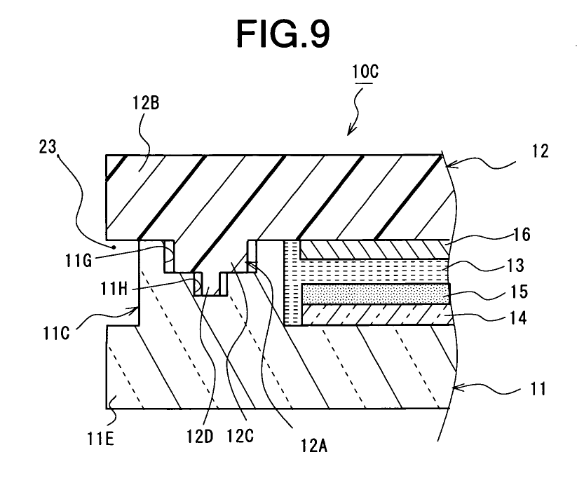

FIG. 9 is a sectional view of a principal part of a dye sensitizing solar battery unit 10C in a third modified example of the first preferred embodiment according to the present invention. In the third modified example, the fitting protruding wall portion 11C and fitted protruding wall portion 12A have different constructions from those of the dye sensitizing solar battery unit 10 in the above described first preferred embodiment. In the third modified example similar to the above described first modified example, the peripheral portion 12B of the counter electrode substrate 12 extends to the outside to such an extent that the flange portion 11E extends. Other constructions of the dye sensitizing solar battery unit 10C in the third modified example are substantially the same as those of the dye sensitizing solar battery unit 10 in the above described first preferred embodiment.

Specifically, as shown in FIG. 9, in the dye sensitizing solar battery unit 10C, the end face of the fitting protruding wall portion 11C of the photoelectrode substrate 11 is formed with a first recessed portion 11G and a second recessed portion 11H in two stages so that the width of the recessed portions decreases in two stages in a depth direction. In accordance with the fitting protruding wall portion 11C having such a two-stage structure, the fitted protruding wall portion 12A of the counter electrode substrate 12 comprises a first protruding portion 12C, which has the same height as the depth of the first recessed portion 11G, and a second protruding portion 12D which is formed on the end face of the first protruding portion 12C at the center thereof. Furthermore, the width of the first protruding portion 12C is smaller than the width of the first recessed portion 11G, and the width of the second protruding portion 12D is smaller than the width of the second recessed portion 11H. Thus, as shown in FIG. 9, when the fitting protruding wall portion 11C engages the fitted protruding wall portion 12A, the end face of the fitting protruding wall portion 11C contacts the substrate surface of the counter electrode substrate 12, and the end face of the first protruding portion 12C contacts the bottom face of the first recessed portion 11G, the end face of the second recessed portion 12D contacting the bottom face of the second recessed portion 11H.

With such a fitting structure, the fitting protruding wall portion 11C tightly contacts the fitted protruding wall portion 12A in vertical directions (in thickness directions) , and there are spaces in lateral directions between the side face of the first protruding portion 12C and the inside wall face of the first recessed portion 11G and between the side face of the second protruding portion 12D and the inside wall face of the second recessed portion 11H.

The adhesion on the bonding face in vertical directions is sufficiently high to prevent the electrolytic solution 13 from leaking out. The spaces formed between the fitted protruding wall portion 12A and the fitting protruding wall portion 11C can serve as spaces for housing therein an adhesive. If the adhesive is filled in the spaces, it is possible to inhibit the adhesive from deteriorating with the electrolytic solution 13, and it is possible to increase the amount of the adhesive, so that it is possible to enhance the bonding strength. Moreover, the spaces formed in the bonding portion between the fitting protruding wall portion 11C and the fitted protruding wall portion 12A can be used as spaces for housing therein excessive adhesion.

In the third modified example, in the peripheral side face of the dye sensitizing solar battery unit 10C, the recessed portion 23 is formed by the flange portion 11E of the photoelectrode substrate 11, the peripheral portion 12B of the counter electrode substrate 12 and the fitting protruding wall portion 11C. Also in the third modified example, if the recessed portion 23 is filled with, e.g., an adhesive or sealing material, the bonding strength can be further improved, so that the durability of the dye sensitizing solar battery unit 10C can be improved.

Furthermore, in the third modified example, the end faces of the first and second protruding portions 12C and 12D of the fitted protruding wall portion 12A may be bonded to the bottom faces of the first and second recessed portions 11G and 11H of the fitting protruding wall portion 11C by, e.g., ultrasonic welding, without the need of any adhesives.

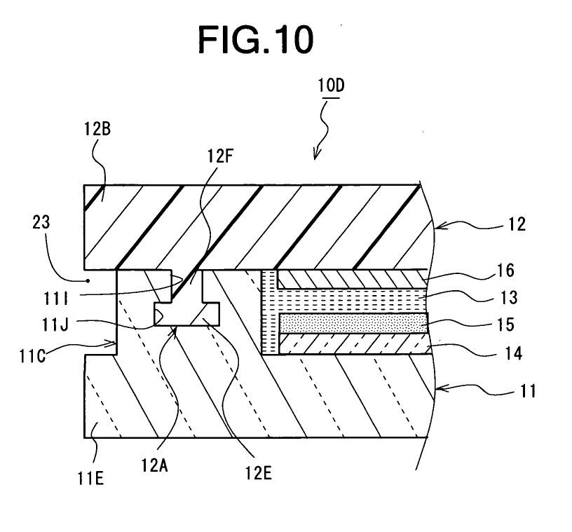

FIG. 10 is a sectional view of a principal part of a dye sensitizing solar battery unit 10D in a fourth modified example of the first preferred embodiment according to the present invention. In this dye sensitizing solar battery unit 10D, the fitting protruding wall portion 11C and the fitted protruding wall portion 12A have different constructions from those of the dye sensitizing solar battery unit 10 in the above described first preferred embodiment. Other constructions of the dye sensitizing solar battery unit 10D in the fourth modified example are substantially the same as those of the dye sensitizing solar battery unit 10 in the above described first preferred embodiment, so that the explanation thereof is omitted.

Specifically, as shown in FIG. 10, in the dye sensitizing solar battery unit 10D, the top end face of the fitting protruding wall portion 11C of the photoelectrode substrate 11 is formed with a groove which comprises a first narrower groove portion 11I and a second wider groove portion 11J, the first groove portion 11I and the second groove portion 11J being arranged in that order in a depth direction. On the other hand, the fitted protruding wall portion 12A of the counter electrode substrate 12 comprises a narrow portion 12F, which has the same width and height as those of the first groove portion 11I of the fitting protruding wall portion 11C to be received in the first groove portion 11I as a base portion, and an expanded portion 12E which extends from the end face of the narrower portion 12F and which has the same width and height as those of the second groove portion 11J of the fitting protruding wall portion 11C to be received in the second groove portion 11J.

With such a fitting structure, the expanded portion 12E is bonded to the second groove portion 11J, so that it is possible to increase the area of the bonding interface. Thus, the area of the whole bonding interface between the fitting protruding wall portion 11C and the fitted protruding wall portion 12A is increased, so that it is possible to more efficiently prevent the electrolytic solution 13 from leaking out to the bonding surface with the adhesive.

In the fourth modified example, in the peripheral side face of the dye sensitizing solar battery unit 10D, the recessed portion 23 is formed by the flange portion 11E of the photoelectrode substrate 11, the peripheral portion 12B of the counter electrode substrate 12 and the fitting protruding wall portion 11C. Also in the fourth modified example, if the recessed portion 23 is filled with, e.g., an adhesive or sealing material, the bonding strength can be further improved, so that the durability of the dye sensitizing solar battery unit 10D can be improved.

Furthermore, in a process for assembling the dye sensitizing solar battery unit 10D in the fourth modified example, if the fitted protruding wall portion 12A is stacked and pressed on the fitting protruding wall portion 11C, the fitted protruding wall portion 12A can be fitted into the first and second groove portions 11I and 11J of the fitting protruding wall portion 11C, so that the photoelectrode substrate 11 can be bonded to the counter electrode substrate 12. If the photoelectrode substrate 11 and the counter electrode substrate 12 are formed of a resin, the expanded portion 12E can press and expand the first groove portion 11I, so that such a fitting method can be achieved. When the fitting is completed, it is possible to enhance the adhesion on the interface between the fitting protruding wall portion 11C and the fitted protruding wall portion 12A by the restoring force of the resin.

Moreover, in the fourth modified example, the surface of the fitted protruding wall portion 12A may be bonded to the inside wall surface of the fitting protruding wall portion 11C by ultrasonic welding, without the need of any adhesives.

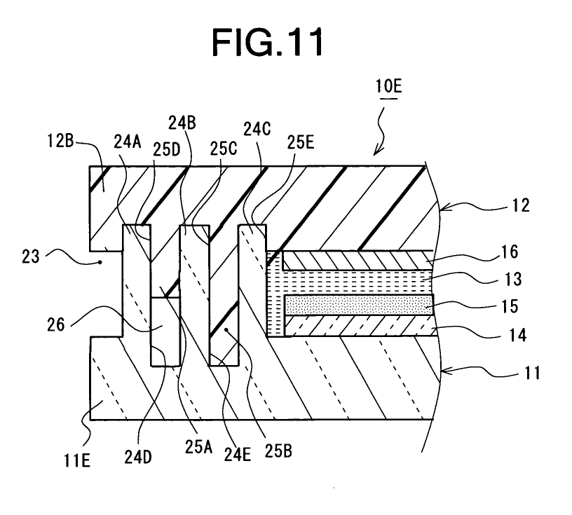

FIG. 11 is a sectional view of a principal part of a dye sensitizing solar battery unit 10E in a fifth modified example of the first preferred embodiment according to the present invention. In the fifth modified example, the fitting structure is different from that of the dye sensitizing solar battery unit 10 in the above described first preferred embodiment. Other constructions in the fifth modified example are substantially the same as those of the dye sensitizing solar battery unit 10 in the above described first preferred embodiment, so that the explanation thereof is omitted.

In the dye sensitizing solar battery unit 10E in the fifth modified example, the photoelectrode substrate 11 is formed with three protruding wall portions 24A, 24B and 24C serving as fitting portions. The protruding wall portions 24A, 24B and 24C protrude at regular intervals from the photoelectrode substrate 11 while extending along the periphery of the photoelectrode substrate 11. Between adjacent two of the three protruding wall portions 24A, 24B and 24C, two grooves 24D and 24E are formed so as to be recessed from the substrate surface of the photoelectrode substrate 11 facing the counter electrode substrate 12.

On the other hand, the counter electrode substrate 12 is formed with two protruding wall portions 25A and 25B serving fitted portions. The protruding wall portions 25A and 25B protrude from the counter electrode substrate 12 while extending along the periphery of the counter electrode substrate 12. Between the protruding wall portions 25A and 25B, and on both sides of the protruding wall portions 25A and 25B, three grooves 25C, 25D and 25E are formed, respectively. Furthermore, the outside protruding wall portion 25A of the two protruding wall portions 25A and 25B is shorter than the other protruding wall portion 25B.

The three protruding wall portions 24A, 24B and 24C of the photoelectrode substrate 11 are fitted into the three grooves 25D, 25C and 25E of the counter electrode substrate 12, respectively. The two protruding wall portions 25A and 25B of the counter electrode substrate 12 are fitted into the two grooves 24D and 24E of the photoelectrode substrate 11. Furthermore, since the outside protruding wall portion 25A is shorter than the depth of the groove 24D, a gap 26 is formed in the groove 24D as shown in FIG. 11 when the protruding wall portion 11 is fitted into the groove 24D. This gap 26 is filled with an adhesive (not shown).

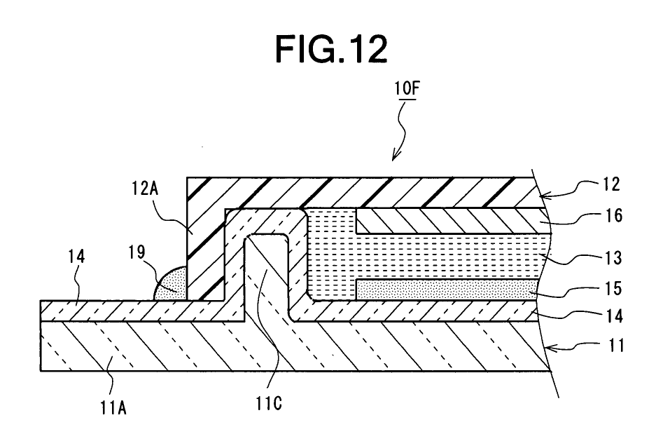

FIG. 12 is a sectional view of a principal part of a dye sensitizing solar battery unit 10F in a sixth modified example in the first preferred embodiment according to the present invention. In this dye sensitizing solar battery unit 10F, a fitting protruding wall portion 11C is also formed on the base portion of the transparent electrode ejecting portion 11A, and the transparent electrode 14 are formed on the fitting protruding wall portion 11C to extend along the surface of the transparent electrode ejecting portion 11A.

In the sixth modified example, as shown in FIG. 12, when the counter electrode substrate 12 is mounted on the photoelectrode substrate 11, the inside surface of the fitted protruding wall portion 12A of the counter electrode substrate 12 can be bonded to the surface of the transparent electrode 14 formed on the surface of the fitting protruding wall portion 11C, so that the fitted protruding wall portion 12A can also be bonded to the transparent electrode ejecting portion 11A in a wider area. Thus, as shown in FIG. 12, even if the end portion of the fitted protruding wall portion 12A is bonded to the transparent electrode 14 with the adhesive 19, it is difficult for the electrolytic solution 13 to contact the adhesive 19. Therefore, in the sixth modified example, it is possible to further prevent the adhesive 19 from deteriorating with the electrolytic solution 13.

Furthermore, other constructions of the dye sensitizing solar battery unit 10F in the sixth modified example are substantially the same as those of the dye sensitizing solar battery unit 10 in the above described first preferred embodiment.

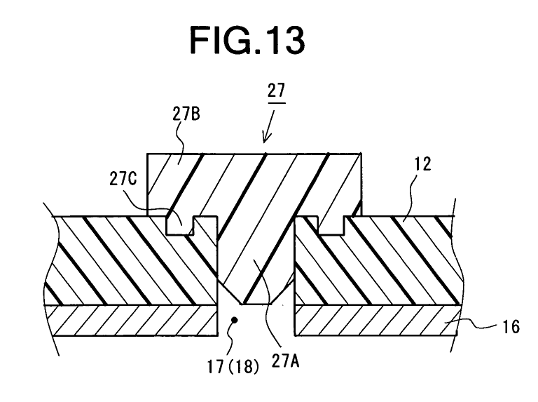

FIG. 13 is a sectional view of a principal part of a seventh modified example of the first preferred embodiment of a dye sensitizing solar battery unit 10 according to the present invention. In the seventh modified example, a closing member 27 shown in FIG. 13 is used in place of the closing member 20 shown in FIG. 5. The closing member 27 comprises a plug portion 27A which is to be inserted into a hole, such as the electrolytic solution injecting hole 17 or exhaust hole 18, a disk-shaped bonding portion 27B which is formed so as to radially extend from the plug portion 27A, and an annular protruding portion 27C which are formed on the bonding portion 27B so as to surround the plug portion 17A, the portions 27A, 27B and 27C being formed of a resin material or the like so as to be integrated with each other. In the surface of the counter electrode substrate 12, a grove into which the protruding portion 27C is to be fitted, is formed so as to surround each of the electrolytic solution injecting hole 17B and the exhaust hole 18. If the closing member 27 having a large contact area to the surface of the counter electrode substrate 12 is thus used for preventing the electrolytic solution 13 from leaking out, it is possible to more sufficiently prevent the electrolytic solution from leaking out of the dye sensitizing solar battery unit.

[Second Preferred Embodiment]

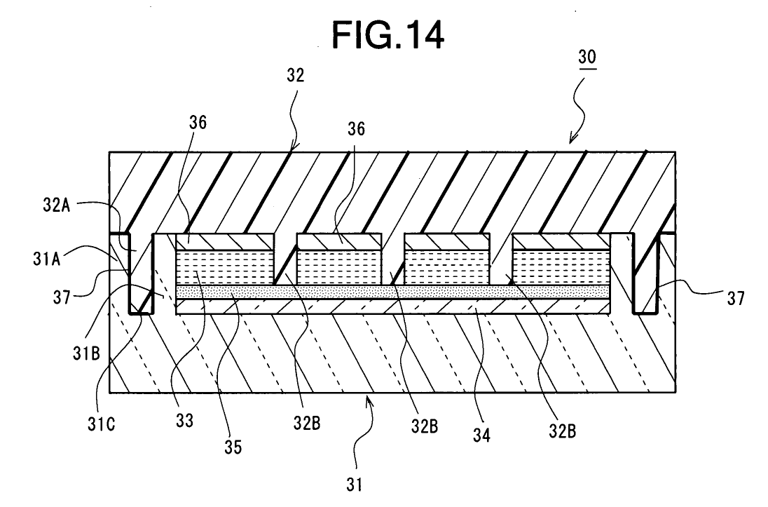

FIG. 14 is a sectional view of the second preferred embodiment of a dye sensitizing solar battery unit according to the present invention. The dye sensitizing solar battery unit 30 in this preferred embodiment generally comprises a photoelectrode substrate 31, a counter electrode substrate 32 facing the photoelectrode substrate 31, and an electrolytic solution 33 filled in a space defined by the substrates 31 and 32. In particular, the dye sensitizing solar battery unit 30 in this preferred embodiment is characterized in that the counter electrode substrate 32 is provided with spacer portions 32B.

The photoelectrode substrate 31 is formed of a resin material capable of sufficiently transmitting light to be molded so as to have a rectangular planar shape. The photoelectrode substrate 31 has two fitting protruding wall portions 31A and 31B, which extend in parallel to each other along the periphery of the photoelectrode substrate 31, except for a portion in which a transparent electrode ejecting portion (not shown) is formed, and which protrude from a substrate surface of the photoelectrode substrate 31 (a surface of the photoelectrode substrate 31 facing the counter electrode substrate 32) in a direction perpendicular thereto. Between the fitting protruding wall portions 31A and 31B, a recessed portion 31C is formed. The photoelectrode substrate 31 with such a construction is formed of a resin to be molded by a molding die.

On the substrate surface of the photoelectrode substrate 31 facing the counter electrode substrate 32, a transparent electrode film 34 is formed in the substantially entire region. On the transparent electrode film 34, a porous semiconductor film 35 is stacked. A sensitizing dye is absorbed on the semiconductor film 35.

The counter electrode substrate 32 is formed of a resin, which is substantially the same as or similar to the resin of the above described photoelectrode substrate 31, to be molded by a molding die. It is not required for the counter electrode substrate 32 to have a high light transmittance. The counter electrode substrate 32 substantially has the same rectangular planar shape and size as those of the photoelectrode substrate 31.

The counter electrode substrate 12 has a fitted protruding wall portion 32A which protrudes toward the photoelectrode substrate 31 and which extends along the periphery of the counter electrode substrate 32. The fitted protruding wall portion 32A is designed to be tightly fitted into the recessed portion 31C when the counter electrode substrate 32 is mounted on the photoelectrode substrate 31. In this preferred embodiment, an adhesive 37 is provided on the end face of the fitting protruding wall portion 31A and on the contact surface of the inside wall of the recessed portion 31C with the fitted protruding wall portion 32A of the counter electrode substrate 32, to fix the photoelectrode substrate 31 to the counter electrode substrate 32.

Furthermore, the adhesive 37 may be an epoxy resin, phenol resin, silicon resin or acrylic resin, and may be applied by, e.g., the screen printing using a dispenser.

From the surface of the counter electrode substrate 32 facing the photoelectrode substrate 31, a plurality of spacer portions 32B protrude so as to be arranged at regular intervals. Each of the spacer portions 32B has such a length that the distance between the semiconductor film 35 and a counter electrode 36, which will be described later, is an appropriate distance when the counter electrode substrate 32 is arranged on the photoelectrode substrate 31.

On the surface of the counter electrode substrate 32 facing the photoelectrode substrate 31, the counter electrode 36 coated with a metal of, e.g., platinum, is formed in a region in which the spacer portions 32B are not formed.

While the adhesive 37 has been used as a fixing means on the fitting portion of the photoelectrode substrate 31 to the counter electrode substrate 32 in this preferred embodiment, a fixing technique or material, such as ultrasonic welding or an ultraviolet curable resin, may be used. When an ultraviolet curable resin is used, a masking is preferably applied so as to irradiate only the ultraviolet curable resin with light in order to prevent the dye, which is absorbed on the semiconductor film 35, from being damaged.

Furthermore, other constructions of the dye sensitizing solar battery unit 30 in this preferred embodiment are substantially the same as those of the dye sensitizing solar battery unit 10 in the above described first preferred embodiment. Also in this preferred embodiment, a transparent electrode ejecting portion, an electrolytic solution injecting hole, an exhaust hole and so forth are formed (not shown).

In the above described bonding structure, the adhesive 37 does not directly contact the electrolytic solution 33 filled in the dye sensitizing solar battery unit 30, so that it is difficult for the adhesion 37 to deteriorate with the electrolytic solution 33. Therefore, the bonding strength of the photoelectrode substrate 31 to the counter electrode substrate 32 can be enhanced, so that the durability of the dye sensitizing solar battery unit 30 can be improved.

Since the counter electrode substrate 32 has the spacer portions 32B in this preferred embodiment, it is easy to produce the counter electrode substrate 32 in addition to the advantageous effects of the first preferred embodiment. In other words, since a step of depositing the substrate surface having a complicated structure having the spacer portions 32B is only one step of depositing the counter electrode film 36, a step of removing films adhering to the spacer portions 32B may be only one step, so that it is easy to carry out the process for producing the counter electrode substrate 32.

Moreover, since the spacer portions 32B are not formed on the photoelectrode substrate 31, on which the semiconductor film 35 having the photoelectric transfer function is formed, in this preferred embodiment, there is an advantage in that it is possible to increase the area of the semiconductor film 35 per unit.

[Third Preferred Embodiment]

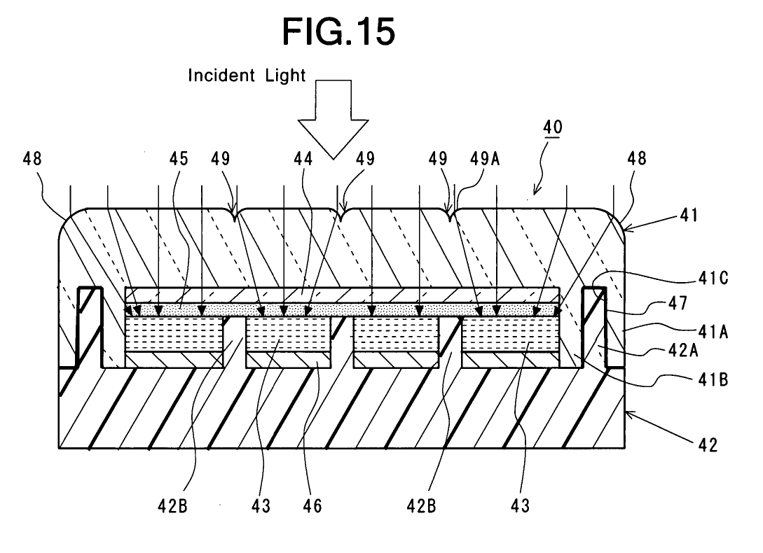

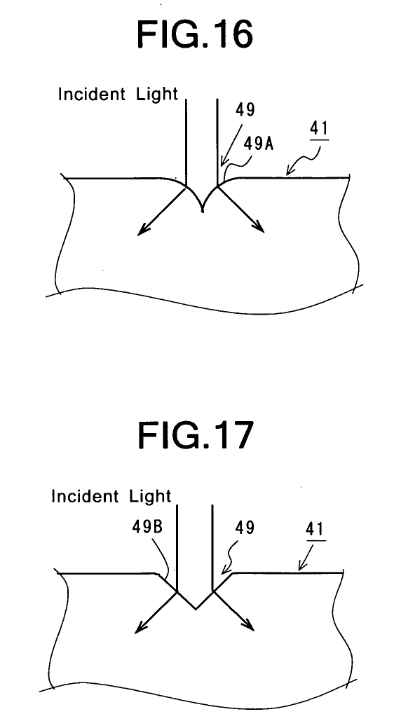

FIGS. 15 and 16 show the third preferred embodiment of a dye sensitizing solar battery unit according to the present invention. The dye sensitizing solar battery unit in this preferred embodiment has a photoelectrode substrate which is light-transmittable and which has the function of condensing incident light on a semiconductor electrode to improve the photoelectric transfer efficiency.

The dye sensitizing solar battery unit 40 in this preferred embodiment generally comprises a photoelectrode substrate 41, a counter electrode substrate 42 facing the photoelectrode substrate 41, and an electrolytic solution 43 serving as an electrolyte filled in a space which is defined by the substrates 41 and 42 to be sealed.

The photoelectrode substrate 41 is formed of a resin material capable of sufficiently transmitting light to be molded so as to have a rectangular planar shape. The photoelectrode substrate 41 has two fitting protruding wall portions 41A and 41B which extend along the periphery of the photoelectrode substrate 41 and which protrude from a substrate surface of the photoelectrode substrate 41 (a surface of the photoelectrode substrate 41 facing the counter electrode substrate 42) in a direction perpendicular thereto so as to have the same height. Between the fitting protruding wall portions 4lA and 41B, a recessed portion 41C is formed.

On the substrate surface of the photoelectrode substrate 41 facing the counter electrode substrate 42, a transparent electrode film 44 is formed in the substantially entire region. On the transparent electrode film 44, a porous semiconductor film 45 is stacked. A sensitizing dye is absorbed on the semiconductor film 45.

On the opposite surface (outside surface) of the photoelectrode substrate 41 to the counter electrode substrate 41, there is formed a structure for changing the traveling direction of incident light. Specifically, as shown in FIG. 15, an R-surface 48 serving as a condensing portion (optical path changing means) is formed on the outside surface of the peripheral portion of the photoelectrode substrate 41 on which the protruding wall portions 41A and 41B are formed. Since incident light shown in FIG. 15 is inwardly deflected on the R-surface 48, the refracted light is incident on the semiconductor film 45 without traveling toward the protruding wall portions 41A and 41B. As shown in FIGS. 15 and 16, on the external surface of portions of the photoelectrode substrate 41 which contact spacer portions 42B, which will be described later, of the counter electrode substrate 42, cone-shaped light deflecting recessed portions 49 having R-surfaces 49A serving as condensing means (optical path changing means) for preventing incident light from linearly traveling to the spacer portions 42B are formed so as to correspond to the spacer portions 42B.

The counter electrode substrate 42 is formed of a resin, which is substantially the same as or similar to the resin of the above described photoelectrode substrate 41, to be molded by a molding die. It is not required for the counter electrode substrate 42 to be light-transmittable. The counter electrode substrate 42 substantially has the same rectangular planar shape and size as those of the photoelectrode substrate 41.

The counter electrode substrate 42 has a fitted protruding wall portion 42A which protrudes toward the photoelectrode substrate 41 and which extends along the periphery of the counter electrode substrate 42. The fitted protruding wall portion 42A is designed to be tightly fitted into the recessed portion 41C of the photoelectrode substrate 41 when the counter electrode substrate 42 is mounted on the photoelectrode substrate 41. The end face of the fitting protruding wall portion 41A and the inside wall of the recessed portion 41C are bonded to the fitted protruding wall portion 42A of the counter electrode substrate 42 with an adhesive 47. Furthermore, the adhesive 47 may be an epoxy resin, phenol resin, silicon resin or acrylic resin, and may be applied by means of, e.g., a dispenser.

While the adhesive 47 has been used as a fixing means on the fitting portion of the photoelectrode substrate 41 to the counter electrode substrate 42 in this preferred embodiment, a fixing technique or material, such as ultrasonic welding or an ultraviolet curable resin, may be used.

From the surface of the counter electrode substrate 42 facing the photoelectrode substrate 41, a plurality of spacer portions 42B protrude so as to be arranged at regular intervals. Each of the spacer portions 42B has such a length that the distance between the semiconductor film 45 and a counter electrode 46, which will be described later, is an appropriate distance when the counter electrode substrate 42 is arranged on the photoelectrode substrate 41.

On the inside surface of the counter electrode substrate 42 (the surface of the counter electrode substrate 42 facing the photoelectrode substrate 41), the counter electrode 46 coated with a catalyst of, e.g., platinum, is for medina region in which the spacer portions 42B are not formed.

Furthermore, other constructions of the dye sensitizing solar battery unit 40 in this preferred embodiment are substantially the same as those in the above described first preferred embodiment. Also in this preferred embodiment, a transparent electrode ejecting portion, an electrolytic solution injecting hole, an exhaust hole and so forth are formed (not shown).

In the dye sensitizing solar battery unit 40 in this preferred embodiment, the substrate surface of the photoelectrode substrate 41, on which light is incident, has the R-surfaces 48 and the light deflecting recessed portions 49 having the R-surfaces 49A. Therefore, it is possible to change the traveling direction of useless incident light, which travels toward the fitting portions and spacer portions 42B of the dye sensitizing solar battery unit 40, toward the semiconductor film 45 for carrying out photoelectric transfer, to enhance the efficiency of light energy to be utilized. In particular, in this preferred embodiment, the photoelectrode substrate 42 is formed of a transparent resin, so that there is an advantage in that the R-surfaces 48 and light deflecting recessed portions 49 serving as condensing portions can be simply molded by a molding die.

In the dye sensitizing solar battery unit 40 in this preferred embodiment, the adhesive 47 does not directly contact the electrolytic solution 43 filled in the dye sensitizing solar battery unit 40, so that it is difficult for the adhesion 47 to deteriorate with the electrolytic solution 43. Therefore, in the dye sensitizing solar battery unit 40 in this preferred embodiment, the bonding strength of the photoelectrode substrate 41 to the counter electrode substrate 42 can be enhanced, so that the durability of the dye sensitizing solar battery unit 40 can be improved.

Since the counter electrode substrate 42 has the spacer portions 42B in this preferred embodiment, it is possible to easily produce the counter electrode substrate 42 in addition to the advantageous effects of the first preferred embodiment. In other words, since a step of depositing the substrate surface having a complicated structure having the spacer portions 42B is only one step of depositing the counter electrode 46, it is possible to easily produce the counter electrode substrate 42.

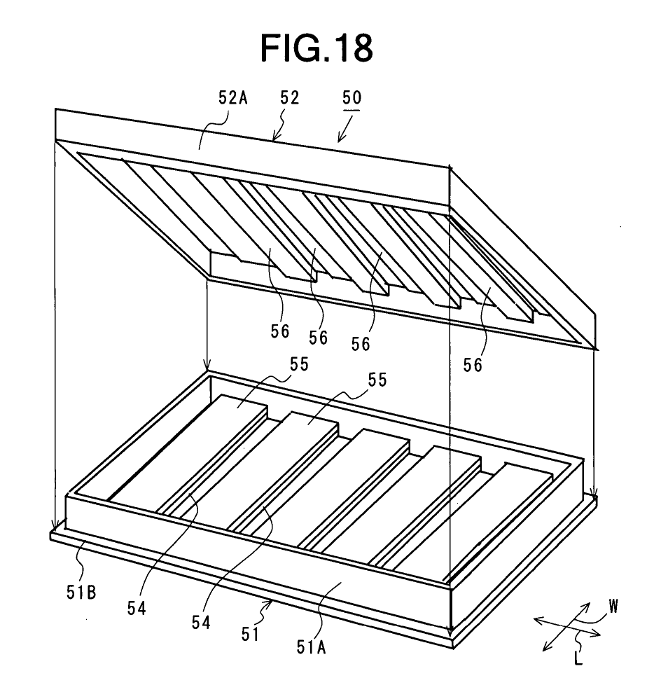

FIG. 17 is a sectional view of a principal part of a modified example of the third preferred embodiment of a dye sensitizing solar battery unit 40 according to the present invention.

In the modified example shown in FIG. 17, linearly inclined surfaces 49B are formed in place of the R-surfaces 49A forming the cone-shaped light deflecting recessed portions 49 shown in FIGS. 15 and 16. The light deflecting recessed portions 49 formed by such inclined surfaces 49B can also provide the same operation and advantageous effects as those in the above described third preferred embodiment.

[Fourth Preferred Embodiment]

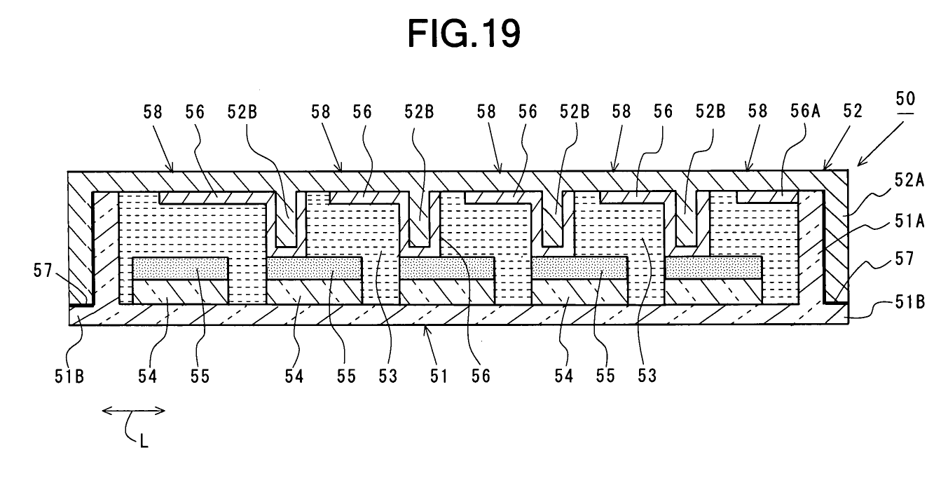

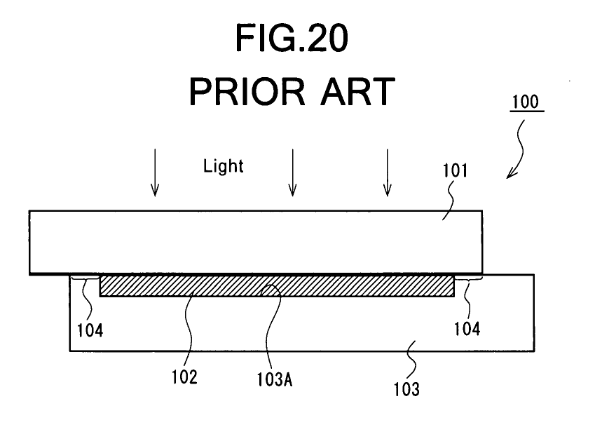

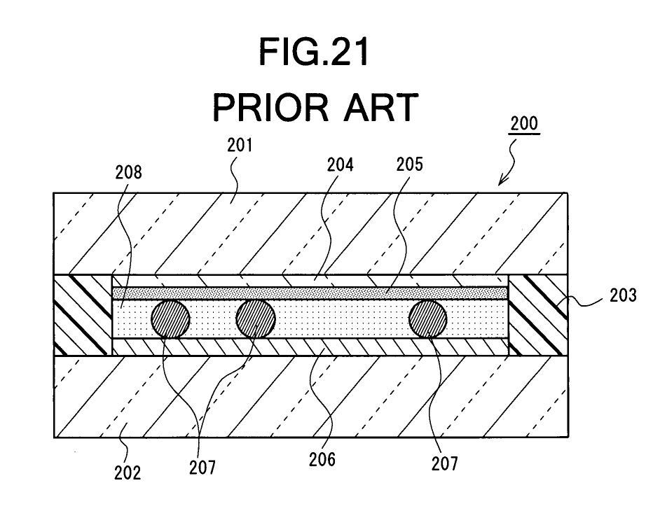

FIGS. 18 and 19 show the fourth preferred embodiment of a dye sensitizing solar battery unit 50 according to the present invention. FIG. 18 is an exploded perspective view of the dye sensitizing solar battery unit 50, and FIG. 19 is a sectional view of the dye sensitizing solar battery unit 50. In this preferred embodiment, the dye sensitizing solar battery unit 50 has a plurality of battery structures.

As shown in FIGS. 18 and 19, the dye sensitizing solar battery unit 50 generally comprises a photoelectrode substrate 51, a counter electrode substrate 52, and an electrolytic solution 53 filled in a space defined by the substrates 51 and 52.

The photoelectrode substrate 51 is formed of a resin material capable of sufficiently transmitting light, and has a rectangular planar shape. On the peripheral portion of the photoelectrode substrate 51, a fitting protruding wall portion 51A serving as a fitting portion is formed so as to extend along the periphery of the photoelectrode substrate 51. In a region surrounded by the fitting protruding wall portion 51A, a plurality of strip-like transparent electrode films 54 extending in lateral directions W are formed at regular intervals in longitudinal directions L, and a plurality of strip-like semiconductor films 55 having the same planar shape and size as those of the transparent electrode films 54 are staked thereon, respectively. Thus, plural columns (five columns in FIGS. 18 and 19) of laminated structures of the transparent electrode films 54 and semiconductor films 55 are arranged at regular intervals in longitudinal directions L.

Of the laminated structures of the transparent electrode films 54 and semiconductor films 55, the transparent film 54 of one of the laminated structures arranged at one end in longitudinal directions L extends to the outside of the photoelectrode substrate 51 (not shown).

The photoelectrode substrate 51 has a flange portion 51B having a predetermined width which extends outside of the fitting protruding wall portion 51A. The photoelectrode substrate 51 with such a structure is formed of a resin to be molded by a molding die.

The counter electrode substrate 52 is formed of a resin, which is the same as or similar to that of the above described photoelectrode substrate 50, to be molded by a molding die. It is not required for the counter electrode substrate 52 to be light-transmittable. As shown in FIG. 18, the counter electrode substrate 52 substantially has the same planar shape and size as those of the photoelectrode substrate 51.

On the periphery of the counter electrode substrate 52, a fitted protruding wall portion 52A serving as a fitted portion is formed so as to protrude toward the photoelectrode substrate 51 facing the counter electrode substrate 52. The fitting protruding wall portion 51A of the photoelectrode substrate 51 is designed to be tightly fitted into a space surrounded by the fitted protruding wall portion 52A of the counter electrode substrate 52 when the counter electrode substrate 52 is mounted on the photoelectrode substrate 51. The height of the fitted protruding wall portion 52A of the counter electrode substrate 52 is substantially equal to the height of the fitting protruding wall portion 51A of the photoelectrode substrate 51.

As shown in FIG. 19, in a region surrounded by the fitted protruding wall portion 52A on the counter electrode substrate 52, a plurality of (four in this preferred embodiment) rib-like spacer portions 52B extending in lateral directions W and protruding in vertical directions are formed at regular intervals in longitudinal directions L. The distance between the vertically extending central planes of adjacent two of the spacer portions 52B is equal to the distance between the vertically extending central planes of adjacent two of the laminated structures of the transparent electrode films 54 and semiconductor films 55 formed on the photoelectrode substrate 51. As shown in FIGS. 18 and 19, each of the spacer portions 52B is arranged so as to face a portion in the vicinity of one edge, in longitudinal directions L, of the top face of the semiconductor film 55 of a corresponding one of the laminated structures formed on the photoelectrode substrate 51, except for one of the laminated structures arranged at the one end in longitudinal directions L.

A counter electrode 56 coated with a catalyst of, e.g., platinum, is formed so as to cover each of the spacer portions 52B. Each of the counter electrodes 56 extends from one edge thereof in longitudinal directions L so as to face the next laminated structure adjacent to a corresponding one of the laminated structures facing the corresponding one of the spacer protrusions 52B. On the side of the other end of the counter electrode substrate 52 in longitudinal directions L, a counter electrode 56A is formed on the counter electrode substrate 52 so as to face one of the laminated structures arranged on the side of the other end of the counter electrode substrate 52 in longitudinal directions L.

When the above described photoelectrode substrate 51 and counter electrode substrate 52 are bonded to each other, the structure shown in FIG. 19 is obtained. That is, the fitting protruding wall portion 51A of the photoelectrode substrate 51 is tightly fitted into the space defined by the fitted protruding wall portion 52A of the counter electrode substrate 52. In this preferred embodiment, the height of the fitting protruding wall portion 51A is equal to the height of the fitted protruding wall portion 52A. Therefore, as shown in FIG. 19, the end face of the fitting protruding wall portion 51A tightly contacts the inside surface of the counter electrode substrate 52 (the surface of the counter electrode 52 facing the photoelectrode substrate 51), and the end face of the fitted protruding wall portion 52A of the counter electrode substrate 52 tightly contacts the top face of the flange portion 51B of the photoelectrode substrate 51 (the surface of the flange portion 51B facing the counter electrode substrate 52). Thus, the fitting protruding wall portion 51A is tightly fitted into the space defined by the fitted protruding wall portion 52A, so that it is possible to hold fluid-tightness. As shown in FIG. 19, in this preferred embodiment, the end face and inside surface of the fitted protruding wall portion 52A of the counter electrode substrate 52 are bonded to the top face of the flange portion 51B of the photoelectrode substrate 51 and the outside surface of fitting protruding wall portion 51A thereof with an adhesive 57. Thus, the adhesive 57 does not contact the electrolytic solution 53 filled in the dye sensitizing solar battery unit 50, so that it is possible to prevent the adhesive 57 from deteriorating with the electrolytic solution 53. Therefore, in the dye sensitizing solar battery unit 50 in this preferred embodiment, it is possible to enhance the bonding strength of the photoelectrode substrate 51 to the counter electrode substrate 52, so that it is possible to improve the durability of the dye sensitizing solar battery unit 50.

As shown in FIG. 19, the counter electrodes 56, which cover the spacer portions 52B protruding from the counter electrode substrate 52, contact the semiconductor films 55 serving as the upper layer of the laminated structures on the photoelectrode substrate 51. With such a construction, the distance between the photoelectrode substrate 51 and the counter electrode substrate 52 is held to be a predetermine distance. In each of spaces separated by each of the spacer portions 52B to be formed on both sides, there is provided a battery part 58 comprising the semiconductor film 55 and the counter electrode 56 facing the semiconductor film 55 via the electrolytic solution 53. As shown in FIG. 19, the counter electrode 56 of each of the battery parts 58 is connected to the semiconductor film 55 of the next battery part 58 adjacent thereto in longitudinal directions L. Thus, the battery parts 58 are electrically connected in series. In such a construction, electrodes serving as anode and cathode are extended from the battery parts 58 on both ends in longitudinal directions L, so that it is possible to obtain electric energy of a voltage value generated by the battery parts 58.

In this preferred embodiment, a method for sealing the electrolytic solution 53 may be the same method as that in the above described first preferred embodiment.

While the adhesive 57 has been used as a fixing means on the fitting portion of the photoelectrode substrate 51 to the counter electrode substrate 52 in the above described preferred embodiment, a fixing technique or material, such as ultrasonic welding or an ultraviolet curable resin, may be used.

In this preferred embodiment similar to the above described third preferred embodiment, the photoelectrode substrate 51 may have an optical path changing structure for changing the traveling direction of incident light, which is intended to travel toward the peripheral portions and spacer portions 52B, toward the semiconductor films 55.

Since the battery parts 58 are connected in series in this preferred embodiment, the transparent electrode films 54 may be omitted in accordance with the electric characteristics of the semiconductor films 55.

The operation and advantageous effects of the above described fourth preferred embodiment of a dye sensitizing solar battery unit 50 according to the present invention will be described below.

In this preferred embodiment, the fitting protruding wall portion 51A of the photoelectrode substrate 51 is tightly fitted into the space defined by the fitted protruding wall portion 52A of the counter electrode substrate 52. Thus, the substrates 51 and 52 are bonded to each other with the adhesive 57 in a region of the bonding interface in which it is difficult to directly contact the electrolytic solution 53, so that it is difficult for the adhesive 57 to deteriorate with the electrolytic solution 53. Therefore, it is possible to improve the bonding strength between the photoelectrode substrate 51 and the counter electrode substrate 52, so that it is possible to improve the durability of the dye sensitizing solar battery unit 50.

In the dye sensitizing solar battery unit 50 in this preferred embodiment, the plurality of battery parts 58 are connected in series, so that one unit can obtain a power of a high voltage.

[Other Preferred Embodiment]

While the photoelectrode substrate and the counter electrode substrate have been formed of the resin in the above described first through fourth preferred embodiments, they may be formed of a glass or the like according to the present invention.

While the photoelectrode substrate has been formed of the transparent material for allowing light to be incident on the photoelectrode substrate in the above described first through fourth preferred embodiments, the counter electrode film may be transparent for allowing light to be incident on the counter electrode substrate.

While the electrolytic solution has been used as an electrolyte in the above described first through fourth preferred embodiments, a polymer electrolyte may be used.

As described above, according to the present invention, it is possible to realize a dye sensitizing solar battery unit having bonding portions having a high durability, and a sealing structure for the dye sensitizing solar battery unit.

According to the present invention, it is possible to improve the uniformity of a gap between the substrates of the dye sensitizing solar battery unit.

According to the present invention, it is possible to realize a dye sensitizing solar battery unit having a high power generation efficiency since the substrate has the condensing function.

According to the present invention, it is possible to realize a dye sensitizing solar battery unit which can easily align substrates with each other and which can be produced at low costs.

While the present invention has been disclosed in terms of the preferred embodiment in order to facilitate better understanding thereof, it should be appreciated that the invention can be embodied in various ways without departing from the principle of the invention. Therefore, the invention should be understood to include all possible embodiments and modification to the shown embodiments which can be embodied without departing from the principle of the invention as set forth in the appended claims.

What is claimed is:

1. A dye sensitizing solar battery unit comprising:
a photoelectrode substrate on which a semiconductor electrode is formed;
a counter electrode substrate on which a counter electrode is formed; and
an electrolyte filled in a space defined by said photoelectrode substrate and said counter electrode substrate,
said counter electrode facing said semiconductor electrode via said electrolyte so that a potential difference is produced between the counter electrode and the semiconductor electrode by photoelectric transfer,
wherein one of said photoelectrode substrate and said counter electrode substrate has a fitting portion which is formed so as to surround a region in which said semiconductor electrode faces said counter electrode, and the other of said photoelectrode substrate and said counter electrode substrate has a fitted portion which is formed so as to surround said region, said fitting portion being fitted into a space defined by said fitted portion.

2. A dye sensitizing solar battery unit as set forth in claim 1, wherein said fitted portion is a protruding wall which protrudes from the other of said photoelectrode substrate and said counter electrode substrate toward the one of said photoelectrode substrate and said counter electrode substrate.

3. A dye sensitizing solar battery unit as set forth in claim 1, wherein said photoelectrode substrate and said counter electrode substrate are formed of a resin.

4. A dye sensitizing solar battery unit as set forth in claim 3, wherein said fitting portion is bonded or welded to said fitted portion in a bonding surface which is apart from said electrolyte.

5. A dye sensitizing solar battery unit as set forth in claim 1, which further comprises a spacer portion which is formed so as to be integrated with one of said photoelectrode substrate and said counter electrode substrate for holding a predetermined distance between said photoelectrode substrate and said counter electrode substrate.

6. A dye sensitizing solar battery unit as set forth in claim 1, wherein one of said photoelectrode substrate and said counter electrode substrate is light-transmittable, and has a condensing portion for changing a traveling direction of incident light toward said semiconductor electrode.

7. A substrate assembly for a dye sensitizing solar battery unit, said substrate assembly comprising:
a photoelectrode substrate on which a semiconductor electrode is formed; and
a counter electrode substrate on which a counter electrode is formed, said counter electrode facing said semiconductor electrode,
wherein one of said photoelectrode substrate and said counter electrode substrate has a fitting portion which is formed so as to surround a region in which said semiconductor electrode faces said counter electrode, and the other of said photoelectrode substrate and said counter electrode substrate has a fitted portion which is formed so as to surround said region, said fitting portion being fitted into a space defined by said fitted portion.

8. A substrate assembly for a dye sensitizing solar battery unit as set forth in claim 7, wherein said photoelectrode substrate and said counter electrode substrate are formed of a resin, and said photoelectrode substrate is light-transmittable.

9. A substrate assembly for a dye sensitizing solar battery unit as set forth in claim 7, which further comprises a spacer portion which is formed so as to be integrated with one of said photoelectrode substrate and said counter electrode substrate for holding a predetermined distance between said photoelectrode substrate and said counter electrode substrate.

10. A substrate assembly for a dye sensitizing solar battery unit as set forth in claim 7, wherein one of said photoelectrode substrate and said counter electrode substrate has a condensing portion for changing a traveling direction of incident light toward said semiconductor electrode.

11. A sealing structure for sealing a dye sensitizing solar battery unit, said sealing structure comprising:
a fitting portion formed on one of a photoelectrode substrate on which a semiconductor electrode is formed, and a counter electrode substrate on which a counter electrode is formed, said counter electrode facing said semiconductor electrode via an electrolyte, which is filled in a space defined by said photoelectrode substrate and said counter electrode substrate, so that a potential difference is produced between said counter electrode and said semiconductor electrode by photoelectric transfer, said fitting portion extending so as to surround a region in which said semiconductor electrode faces said counter electrode; and
a fitted portion formed on the other of said photoelectrode substrate and said counter electrode substrate, said fitted portion extending so as to surround said region, said fitting portion being fitted into a space defined by said fitted portion.

12. A sealing structure as set forth in claim 11, wherein said fitting portion is bonded or welded to said fitted portion in a region which is apart from said electrolyte.
